(19) United States
(12) Patent Application Publication
(10) Pub. No.: US 2006/0179950 A1
(43) Pub. Date: Aug. 17, 2006

(54) Method for forming a pressure proof assembly between a component and house and such an assembly

(75) Inventor: Per Brant Rasmussen, Augustenborg (DK)

Correspondence Address: MCCORMICK, PAULDING & HUBER LLP, CITY PLACE II, 185 ASYLUM STREET, HARTFORD, CT, 06103, US

(73) Assignee: A/S, Nordborg (DK)

(21) Appl. No.: 10/559,770

(22) PCT Filed: Jun. 8, 2004
(86) PCT No.: PCT/DK04/00390

§ 371 Date: Dec. 8, 2005

(30) Foreign Application Priority Data
Jun. 10, 2003 (DK) PA 2003 00859

(51) Int. Cl. H01R 9/00; H05K 3/30; G01L 19/04

(52) U.S. Cl. 73/708; 29/842; 29/841; 277/581

(57) ABSTRACT

The present invention relates to a method for pressure proof and tight assembling of a component to a wall of a house. The method is applicable for assembling components which are sensitive to high temperatures, e.g. for assembling an electronic pressure sensor in a house. According to the invention is component and the house is assembled via a sealing member, e.g. a sleeve, which is pressed into an opening between the component and the house until the yield point is exceeded for at least one of the component, the house and the sealing member.

### CROSS REFERENCE TO RELATED APPLICATIONS

This application is entitled to the benefit of and incorporates by reference essential subject matter disclosed in International Patent Application No. PCT/DK2004/000390 filed on Jun. 8, 2004 and Danish Patent Application No. PA 2003 00859 filed Jun. 10, 2003.

### FIELD OF THE INVENTION

The present invention relates to a method for pressure proof encapsulation of a component, in particular a temperature sensitive component to be attached in a house separating systems of different pressures, e.g. for encapsulation of a pressure sensor in a pressure or vacuum chamber or in a combustion engine. The invention further relates to a pressure sensor encapsulated in a house in accordance with the method.

### BACKGROUND OF THE INVENTION

In general, pressure sensors and similar components sealed in a lead-in between a high pressure and a low pressure side of a house and methods for sealing such components into a lead-in exist. In combustion engines such as diesel engines, pressure sensors are typically mounted in the cylinder head for measuring the combustion pressure during operation of the engine and many similar fields of operation in connection with low and high pressure systems can be mentioned. Due to large pressure differences between the inside and the outside of the house, the sealing between the component and the lead-in must be pressure proof and capable of sustaining large forces. Most often, the components are bonded adhesively to the lead-in, e.g. during a process wherein a glass or alloy based material is melted into adhesive contact with the component and the house by heating the house, the component and the glass or alloy based material, e.g. glass frit, to very high temperatures, e.g. up to 600° C. or even more. In particular for sealing elongated silicon pressure sensors into metal houses, glass frit material can be selected since the thermal coefficients of expansion of the materials are progressively increasing relative to the silicon sensing element. This allows strong bonding of the materials, thereby minimizing any pressure leakage.

U.S. Pat. No. 6,505,398 and EP 0 354 479 both disclose an elongate element of silicon connected to a metal house via melted glass and or ceramic pastes. Even though the disclosed processes can be used for establishing a strong bonding and a completely sealed connection between the component and the house, the high temperatures required to melt the glass based material can cause dimensional deflections or in other ways deteriorate the house and components encapsulated therein.

In particular, electrical pressure sensors and similar components comprising sets of electrical conductors and terminals may be influenced by the excessive heating. These conductors and terminals are often made by deposition of a very thin layer of metal, e.g. aluminium, formed on the surface of a base material, e.g. onto a rod made of silicon, to allow subsequent interconnection, e.g. by welding or soldering, to external components. If such thin layers of a conductive metal are subjected to high temperatures, they may melt into the base material or evaporate whereby the conductivity, solderability or weldability is reduced or disappears. In order to avoid this, methods known in the art prescribe that the components are sealed into the house in a state prior to deposition of the metal termination layers. Subsequent to the heating process, metal layers have to be applied individually for each sensor to the terminal end of the sensor rod in a separate process. Accordingly, the process known in the art requires multiple subsequent processes which are time consuming and expensive.

### BRIEF SUMMARY OF THE INVENTION

It is an object of a preferred embodiment of the present invention to provide a method for forming a pressure proof assembly between a component and a house which enable a more simple manufacturing process, in particular in connection with temperature sensitive components. Accordingly, the present invention in a first aspect relates to a method for forming a pressure proof assembly between a component and a house forming an opening between a high pressure and a low pressure side, said method comprising the steps of:
arranging the component in the opening,
arranging a sealing member between the component and the house, and

pressing the sealing member into contact with the component and the house so that the pressures between the surfaces of the sealing member and the component and between the surfaces of the sealing member and the house exceed the yield point of at least one of the sealing member, the component and the house, so as to seal between the component and the house.

Due to the pressure which exceeds the yield point, the component and the house is brought into completely sealed engagement with the sealing member without use of excessive temperatures and it is therefore possible to use the methods for pressure proof sealing of temperature sensitive components into a house without any complicated pre and post processing of the components.

With a pressure sensor assembly according to the invention, uncovering of a terminal end of a sensor or similar electronic component and deposition of metal termination layers is now possible in a common manufacturing process for a plurality of sensors or similar electronic components or similar temperature sensitive components. As known in the art, a large number of silicon sensors are commonly processed on a silicon-wafer. With the method according to the invention, pressure sensors may now be processed “ready-to-use” prior to the division of the wafer into individual sensor items and subsequent encapsulation in a house.

Preferably, the sealing member is made from a material with a yield point which is relatively low compared to the yield point of the component and house. In that way, it is possible to apply a pressure which exceeds the yield point of the sealing member only and thereby to ensure, that no dimensional changes takes place with respect to the component and house.

In particular, the method is applicable for assembling temperature sensitive components such as electrical components comprising a set of electrical terminals to a house, e.g. for sealing oblong pressure sensors into a metal house. Such components typically have polygonal cross-sectional shapes and may often be made from silicon or glass.

The sealing member could be a preformed sleeve, e.g. an annular body, e.g. a tubular body. The sleeve could be formed with a polygonal shape corresponding to the shape of the component or at least the inner surface of the sleeve, i.e. the surface facing towards the component during the assembling process, could be formed with a polygonal shape matching the shape of the component. The outer surface of the sleeve, i.e. the surface facing towards the house could be made with a different shape, e.g. a circular cross-sectional shape or any other shape matching the shape of the opening in the house.

In order to press the sleeve into contact with the house and the component, at least one of the outer and inner peripheral surfaces may be tapered. As an example, the outer peripheral surface may be tapered for pressing against an inner peripheral surface of the opening in the house during axial pressing of sleeve into the opening. The sleeve should preferably be inserted from the pressure side so that the pressure difference presses the sleeve into stronger contact with the opening of the house.

Similarly, the opening in the house may have an inner peripheral surface which is tapered with a cross sectional area at a first axial end which is larger than a cross sectional area at an opposite second axial end, to exert pressure against a sleeve which is forced into the opening. Preferably, the first axial end of the opening is towards the high pressure side of the house so that the forces caused by the pressure difference and acting on the sleeve in an axial direction, forces the sleeve into stronger contact with the house.

The sleeve can be made from various plastic materials, composite materials comprising plastics or from a material comprising metal, preferably a ductile metal, e.g. tantalum, copper, nickel, indium, niobium or tin.

In order to allow an easier production process and to ensure that the sleeve is properly arranged between the house and the component prior to the application of the pressure, the sleeve or at least a part thereof may be provided with an adhesive component applied to at least one of the outer and inner peripheral surfaces.

According to a second aspect, the present invention relates to an assembly comprising a house, a pressure sensor extending through an opening in the house and a sealing member arranged in the opening between the house and the sensor, the sealing member being pressed into engagement with the sensor and the house under a pressure which exceeds the yield point of at least one of the sealing member, the pressure sensor and the house. Preferably, the sealing member is made from a material comprising a metal selected from the group consisting of tantalum, copper, nickel, indium, niobium and tin.

### BRIEF DESCRIPTION OF THE DRAWINGS

In the following a preferred embodiment of the invention will be described in further details with reference to the drawing in which:

FIG. 1 shows a pressure sensor and a house with a lead-in opening, the gap between the sensor and house being sealed in accordance with the present invention, and

FIGS. 2A-2C shows three different combinations between openings in the house and corresponding sleeves.

### DETAILED DESCRIPTION OF THE INVENTION

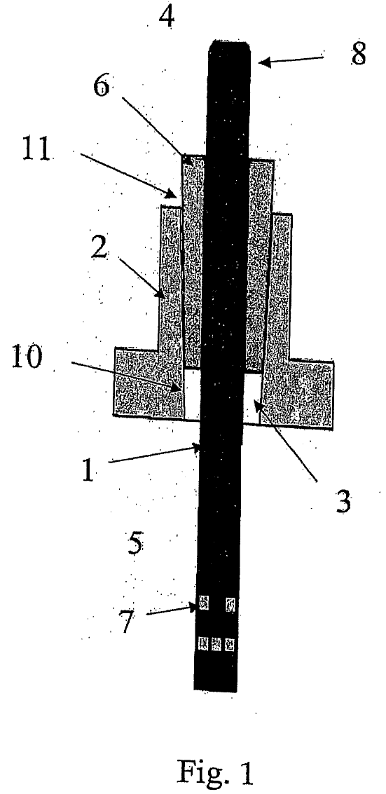

Referring to FIG. 1, the sensor 1 is assembled to a house 2 having a lead-in opening 3 between a first side 4 and a second side 5 of a system, e.g. a vacuum chamber or a combustion engine. The sealing member 6 seals and fixates the sensor in the opening. The sensor is provided in one of its axial end parts with a set of electrically conductive terminals 7 and in the opposite end part with a pressure sensitive tip 8. The sealing member has the shape of a sleeve which is pressed into the gap between the house and the pressure sensor. In the disclosed embodiment, both the inner surface 10 of the lead-in opening and the outer surface 11 of the sleeve are bevelled. Due to the bevelling, pressing of the sleeve in an axial direction from the first side towards the second side will cause a pressure between the outer surface of the sensor rod and the inner surface of the lead-in opening and, due to the flexibility of the sleeve, the pressing will further cause a pressure between the inner surface 12 of the sleeve and the outer surface 13 of the pressure sensor. In other embodiments, only one of the inner surface of the lead-in opening and the outer surface of the sleeve needs to be bevelled.

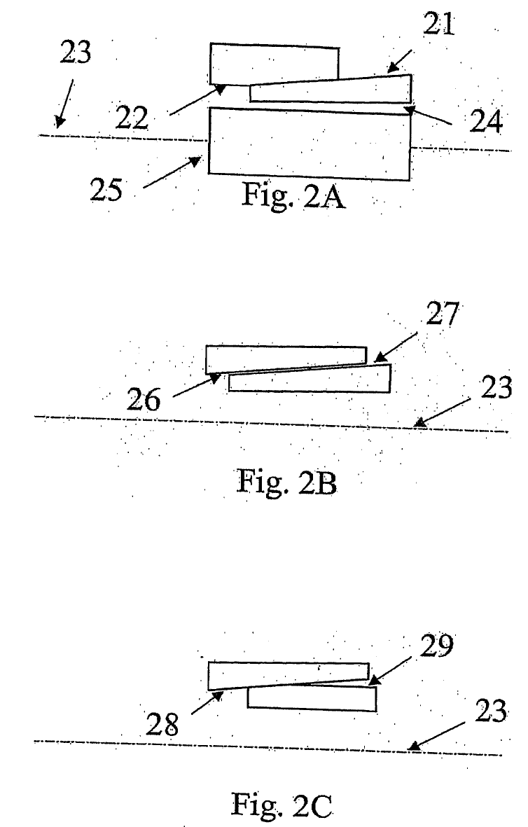

FIGS. 2A, 2B and 2C show three different sleeves for use in the assembling method according to the present invention. The sleeve in FIG. 2A has a tapered outer surface 21 to be pressed into engagement with the opening of the house. The opening of the house has an inner peripheral surface 22 which is parallel and coaxial to the centre axis 23. Upon application of an axially directed pressure to the sleeve, the outer surface 21 and the inner surface 22 is pressed into contact with each other. Due to the pressure, the sleeve is deformed, whereby the inner peripheral surface thereof 24 is squeezed into contact with the component 25, e.g. a pressure sensor. The component 25 is not shown in FIGS. 2B and 2C.

In FIG. 2B, the sleeve has a tapered outer surface 26 to be pressed into engagement with a correspondingly tapered inner surface 27 of the opening upon application of an axially directed pressure to the sleeve.

In FIG. 2C, the inner surface 28 of the opening is tapered whereas the inner and outer surfaces of the sleeve are both parallel to the centre axis 23.

While the present invention has been illustrated and described with respect to a particular embodiment thereof, it should be appreciated by those of ordinary skill in the art that various modifications to this invention may be made without departing from the spirit and scope of the present invention.

1-17. (canceled)

18. A method for forming a pressure proof assembly between a component and a house forming an opening between a high pressure and a low pressure side, said method comprising the steps of:
arranging the component in the opening;
arranging a sealing member between the component and the house, the sealing member forming a sleeve with an annular body with an outer and an inner peripheral surface wherein at least one of the outer and inner peripheral surfaces is tapered; and
pressing the sealing member into contact with the component and the house so that the pressures between the surfaces of the sealing member and the component and between the surfaces of the sealing member and the house exceed the yield point of at least one of the sealing member, the component and the house, so as to seal between the component and the house.

19. The method according to claim 18, wherein the yield point is exceeded for the sealing member.

20. The method according to claim 18, wherein the component is an oblong component comprising a set of electrical terminals.

21. The method according to claim 18, wherein the component has a polygonal cross-sectional shape.

22. The method according to claim 19, wherein the component comprises a pressure sensor.

23. The method according to claim 19, wherein the component is made from a material selected from the group consisting of silicon and glass.

24. The method according to claim 18, wherein the sleeve has a circular cross-sectional shape.

25. The method according to claim 18, wherein the sleeve is made of a ductile material.

26. The method according to claim 18, wherein the sleeve is provided with an adhesive component applied to at least one of the outer and inner peripheral surfaces.

27. The method according to claim 18, wherein the sleeve is made from a material comprising a metal selected from the group consisting of tantalum, copper, nickel, indium, niobium and tin.

28. The method according to claim 18, wherein the opening has a cross sectional area at a first axial end which is larger than a cross sectional area at an opposite second axial end.

29. The method according to claim 28, wherein the first axial end of the opening is towards the high pressure side of the house.

30. An assembly comprising a house, a pressure sensor extending through an opening in the house and a sealing member arranged in the opening between the house and the sensor, the sealing member forming a sleeve with an annular body with an outer and an inner peripheral surface wherein at least one of the outer and inner peripheral surfaces is tapered, the sealing member being pressed into engagement with the sensor and the house under a pressure which exceeds the yield point of at least one of the sealing member and the house.

31. The assembly according to claim 30, wherein the sealing member is made from a material comprising a metal selected from the group consisting of tantalum, copper, nickel, indium, niobium and tin.
